(19) United States
(12) Patent Application Publication
(10) Pub. No.: US 2024/0249063 A1
(43) Pub. Date: Jul. 25, 2024

(54) TRAINING METHOD AND APPARATUS FOR CHIP LAYOUT ENCODER AND CHIP LAYOUT SCREENING METHOD AND APPARATUS

(71) Applicant: Tencent Technology (Shenzhen) Company Limited, Shenzhen (CN)

(72) Inventors: Xingyu MA, Shenzhen (CN); Shaogang HAO, Shenzhen (CN); Shengyu ZHANG, Shenzhen (CN)

(21) Appl. No.: 18/625,056

(22) Filed: Apr. 2, 2024

Related U.S. Application Data
(63) Continuation of application No. PCT/CN23/97408, filed on May 31, 2023.

(30) Foreign Application Priority Data
Sep. 26, 2022 (CN) 202211176018.8

(51) Int. Cl. G06F 30/392; G06F 30/398

(52) U.S. Cl. CPC G06F 30/392; G06F 30/398

(57) ABSTRACT

A chip layout screening method is performed by an electronic device, and belong to the field of integrated circuit technologies. The method includes: obtaining a plurality of target chip layouts and a chip layout encoder; extracting target layout features of the plurality of target chip layouts by using the chip layout encoder; performing clustering on the plurality of target chip layouts based on the target layout features to obtain a plurality of target clusters, wherein each target cluster comprises a group of target chip layouts; and identifying a key chip layout from a respective group of target chip layouts. The chip layout encoder focuses on extracting a layout feature that can distinguish between chip layout types. This helps improve accuracy of a clustering result when chip layouts are subsequently clustered based on the layout feature.

### CROSS-REFERENCE TO RELATED APPLICATIONS

This application is a continuation application of PCT Patent Application No. PCT/CN2023/097408, entitled “TRAINING METHOD AND APPARATUS FOR CHIP LAYOUT ENCODER AND CHIP LAYOUT SCREENING METHOD AND APPARATUS” filed on May 31, 2023, which claims priority to Chinese Patent Application No. 202211176018.8, entitled “TRAINING METHOD AND APPARATUS FOR CHIP LAYOUT ENCODER AND CHIP LAYOUT SCREENING METHOD AND APPARATUS” filed on Sep. 26, 2022, all of which is incorporated herein by reference in its entirety.

### FIELD OF THE TECHNOLOGY

Embodiments of this application relate to the field of integrated circuit technologies, and in particular, to a training method and apparatus for a chip layout encoder and a chip layout screening method and apparatus.

### BACKGROUND OF THE DISCLOSURE

With continuous development of integrated circuit (IC) technologies, a feature size of an IC layout (also referred to as a chip layout) is continuously reduced. The feature size of the chip layout is a minimum size of a semiconductor device. Currently, the feature size of the chip layout has reached a nanometer level.

Generally, a lithography machine needs to be invoked to expose the chip layout on photosensitive adhesive by using a source, to obtain a mask layout, and then the lithography machine is invoked to expose the mask layout on a wafer by using the source, to obtain an imaging layout. Because the feature size of the chip layout is less than a source wavelength used in a photolithography process, an interference effect and a diffraction effect are enhanced. Consequently, an imaging layout obtained by exposing the mask layout on the wafer is distorted and blurred. This reduces chip performance and yield. In this case, source mask optimization needs to be performed on the chip layout, to obtain an optimized mask layout, thereby improving chip performance and yield.

When source mask optimization is performed on the chip layout, a layout feature of the chip layout needs to be extracted. Therefore, how to obtain, through training, a chip layout encoder that can extract the layout feature of the chip layout is a problem urgently to be resolved.

### SUMMARY

This application provides a training method and apparatus for a chip layout encoder and a chip layout screening method and apparatus, to extract a layout feature of a chip layout and screen chip layouts, where the technical solutions include the following content:

According to one aspect, a chip layout screening method is performed by an electronic device and including:
obtaining a plurality of target chip layouts and a chip layout encoder;
extracting target layout features of the plurality of target chip layouts by using the chip layout encoder;
performing clustering on the plurality of target chip layouts based on the target
layout features to obtain a plurality of target clusters, wherein each target cluster comprises a group of target chip layouts; and
identifying a key chip layout from a respective group of target chip layouts.

According to another aspect, an electronic device is provided, including a processor and a memory, the memory storing at least one computer program, and the at least one computer program being loaded and executed by the processor, so that the electronic device implements the foregoing chip layout screening method.

According to another aspect, a non-transitory computer-readable storage medium is further provided, storing at least one computer program, the at least one computer program being loaded and executed by a processor of an electronic device, so that the electronic device implements the foregoing chip layout screening method.

According to the technical solution provided in this application, geometric transformation is performed on the sample chip layout to obtain the reference chip layout, and the initial encoder is trained by using the layout feature of the sample chip layout and the layout feature of the reference chip layout to obtain the chip layout encoder. Therefore, the chip layout encoder can output similar layout features for chip layouts before and after geometric transformation. The chip layouts before and after geometric transformation belong to the same chip layout type. Therefore, the chip layout encoder focuses on extracting a layout feature that can distinguish between chip layout types. This helps improve accuracy of a clustering result and reduces redundancy of a screening result when clustering and screening processing are subsequently performed on chip layouts based on the layout feature.

### BRIEF DESCRIPTION OF THE DRAWINGS

FIG. 1 is a schematic diagram of an implementation environment of a method for training a chip layout encoder or a chip layout screening method according to an embodiment of this application.

FIG. 2 is a flowchart of a method for training a chip layout encoder according to an embodiment of this application.

FIG. 3 is a schematic diagram of performing geometric transformation on a sample chip layout according to an embodiment of this application.

FIG. 4 is a schematic diagram of a Unet framework according to an embodiment of this application.

FIG. 5 is a flowchart of a chip layout screening method according to an embodiment of this application.

FIG. 6 is a schematic diagram of a chip layout encoder and performing clustering and screening based on the chip layout encoder according to an embodiment of this application.

FIG. 7 is a schematic structural diagram of an apparatus for training a chip layout encoder according to an embodiment of this application.

FIG. 8 is a schematic structural diagram of a chip layout screening apparatus according to an embodiment of this application.

FIG. 9 is a schematic structural diagram of a terminal device according to an embodiment of this application.

FIG. 10 is a schematic structural diagram of a server according to an embodiment of this application.

### DESCRIPTION OF EMBODIMENTS

To make objectives, technical solutions, and advantages of this application clearer, the following further describes implementations of this application in detail with reference to the accompanying drawings.

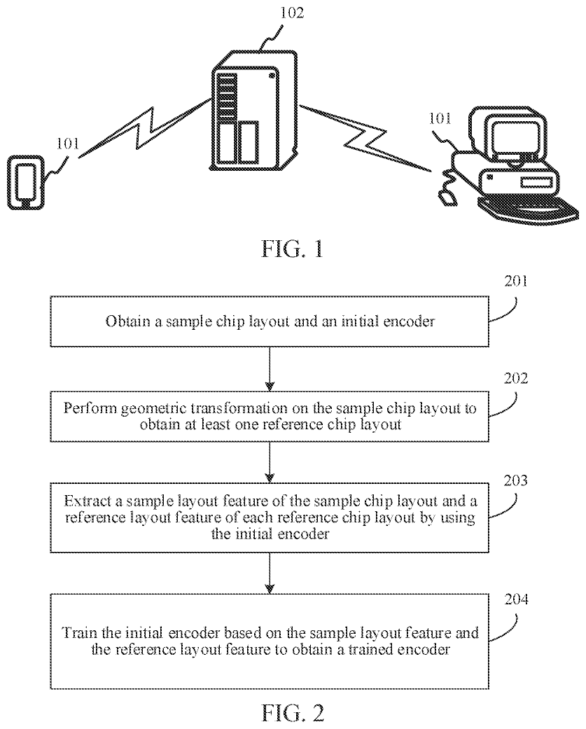

FIG. 1 is a schematic diagram of an implementation environment of a method for training a chip layout encoder or a chip layout screening method according to an embodiment of this application. As shown in FIG. 1, the implementation environment includes a terminal device 101 and a server 102. In this embodiment of this application, the method for training a chip layout encoder or the chip layout screen method may be performed by the terminal device 101, or may be performed by the server 102, or may be performed jointly by the terminal device 101 and the server 102.

The terminal device 101 may be a smartphone, a game console, a desktop computer, a tablet computer, a laptop portable computer, a smart television, a smart in-vehicle device, a smart voice interaction device, a smart home appliance, or the like. The server 102 may be one server, or a server cluster including a plurality of servers, or any one of a cloud computing platform and a virtualization center. This is not limited in this embodiment of this application. The server 102 may communicate with the terminal device 101 by using a wired network or a wireless network. The server 102 may have functions such as data processing, data storage, and data sending/receiving. This is not limited in this embodiment of this application. Quantities of the terminal device 101 and the server 102 are not limited, and there may be one or more terminal devices 101 and one or more servers 102.

The method for training a chip layout encoder or the chip layout screening method provided in this embodiment of this application may be implemented based on an artificial intelligence technology. Artificial intelligence (AI) is a theory, method, technology, and application system that uses a digital computer or a machine controlled by the digital computer to simulate, extend, and expand human intelligence, perceive an environment, acquire knowledge, and use knowledge to obtain an optimal result. In other words, AI is a comprehensive technology in computer science and attempts to understand the essence of intelligence and produce a new intelligent machine that can react in a manner similar to human intelligence. AI is to study the design principles and implementation methods of various intelligent machines, to enable the machines to have the functions of perception, reasoning, and decision-making.

The AI technology is a comprehensive discipline, and relates to a wide range of fields including both hardware-level technologies and software-level technologies. The basic AI technologies generally include technologies such as a sensor, a dedicated AI chip, cloud computing, distributed storage, a big data processing technology, an operating/interaction system, and electromechanical integration. AI software technologies mainly include several major directions such as a computer vision (CV) technology, a speech processing technology, a natural language processing technology, machine learning (ML)/deep learning, automated driving, and intelligent transportation.

In the field of integrated circuit technologies, an integrated circuit layout is a common layout, and the integrated circuit layout is also referred to as a chip layout. Generally, source mask optimization needs to be performed on the chip layout, to obtain an optimized mask layout, so that an error between the chip layout and an imaging layout obtained by exposing the optimized mask layout on a wafer by using a lithography machine is small, thereby improving chip performance and improving chip yield.

When source mask optimization is performed on the chip layout, a layout feature of the chip layout needs to be extracted. Therefore, how to obtain a chip layout encoder through training to extract the layout feature of the chip layout by using the chip layout encoder becomes a problem urgently to be resolved.

An embodiment of this application provides a method for training a chip layout encoder. The method may be applied to the foregoing implementation environment, and a chip layout encoder may be obtained through training. A flowchart of a method for training a chip layout encoder according to an embodiment of this application shown in FIG. 2 is used as an example. For case of description, the terminal device 101 or the server 102 that performs the method for training a chip layout encoder in this embodiment of this application is referred to as an electronic device. The method may be performed by the electronic device. As shown in FIG. 2, the method includes the following steps:

Step 201: Obtain a sample chip layout and an initial encoder.

The sample chip layout is an integrated circuit (IC) layout or a sub-area in the IC layout. Generally, there are a plurality of sample chip layouts, and processing manners of the sample chip layouts are the same.

In this embodiment of this application, any IC layout may be obtained, and the IC layout is used as a sample chip layout. Alternatively, the IC layout may be evenly divided into several sub-areas to obtain each sub-area, and any sub-area is used as a sample chip layout. In some embodiments, a part of sub-areas (for example, a sub-area that does not have a defect spot is obtained through screening, and the defect spot is a part that does not meet a process window requirement in the IC layout) may be manually obtained from the sub-areas through screening, and these sub-areas are used as sample chip layouts. Alternatively, the sub-areas are classified to obtain chip layout types corresponding to the sub-areas, and sub-areas corresponding to the chip layout types are evenly sampled to obtain the sample chip layout through screening. The chip layout type includes but is not limited to a contact hole type, a logical layout type, a dense line type, and the like.

It may be understood that a defect spot may be exactly on a division line when the IC layout is evenly divided. In this case, when the IC layout is divided, one defect spot is divided into at least two parts, and different parts are located in different sub-areas. Because the sub-area includes a part of the defect spot, which is an incomplete defect spot, it is difficult to identify the defect spot from the sub-area. Consequently, the sub-arca including the defect spot is prone to be used as the sample chip layout, which reduces quality of the sample chip layout.

In a possible implementation, each defect spot on the IC layout may be first identified. In this embodiment of this application, a manner of identifying the defect spot is not limited. For example, each defect spot on the IC layout is identified through manual identification, or each defect spot on the IC layout is identified through photolithography simulation. Then, the IC layout is intelligently divided by using an image segmentation model to obtain each sub-area. Through intelligent division, the defect spot is distributed as much as possible in the center of the sub-area instead of an edge of the sub-area. Therefore, when the sample chip layout is obtained from the sub-areas through screening, the defect spot can be quickly and accurately identified from the sub-area, to prevent the sample chip layout obtained through screening from being a sub-area with a defect spot, and improve quality of the sample chip layout. In this way, a training effect of a chip layout encoder can be improved when the chip layout encoder is subsequently trained by using the sample chip layout.

In this embodiment of this application, the sample chip layout is image data, and belongs to a pixel representation manner. The IC layout is divided and the sample chip layout is obtained through screening, so that various chip layout types such as the contact hole type, the logical layout type, and the dense line type can be represented by using pixels. A pixel size of the sample chip layout needs to be greater than or equal to source wavelength/(4×numeric aperture), that is, the pixel size of the sample chip layout needs to meet minimum resolution of a lithography machine.

The sample chip layout is configured for training the initial encoder to obtain the chip layout encoder. A structure, a size, and the like of the initial encoder are not limited in this embodiment of this application. For example, the initial encoder is an encoder in a deep learning framework based on a U network, and is briefly referred to as an encoder in a Unet framework. The encoder in the Unet framework may effectively perform dimension reduction processing on high-dimensional data (for example, image data), to extract a data feature. The Unet framework is a type of convolutional autoencoder, and mainly includes two parts. The first part is an encoder, and includes at least two convolutional blocks. The encoder may be used as the initial encoder in this embodiment of this application. The second part is a decoder, and includes at least two deconvolutional blocks, and a quantity of convolutional blocks is the same as a quantity of deconvolutional blocks.

Step 202: Perform geometric transformation on the sample chip layout to obtain at least one reference chip layout.

Geometric transformation includes at least one type of transformation such as flipping transformation and rotation transformation. At least one type of transformation such as flipping transformation and rotation transformation may be performed on the sample chip layout to obtain the reference chip layout. Flipping transformation is mirror flipping processing mentioned below, and rotation transformation is rotation processing mentioned below.

For example, step 202 includes: performing mirror flipping processing on the sample chip layout to obtain a symmetric chip layout, and using the symmetric chip layout as the at least one reference chip layout. It may be understood that the symmetric chip layout herein may also be referred to as a sample chip layout obtained after mirror flipping processing, which is briefly referred to as a flipped chip layout. In other words, mirror flipping is performed on the sample chip layout to obtain the flipped chip layout. The at least one reference chip layout includes the flipped chip layout. The following describes an implementation of mirror flipping processing, and details are not described herein again.

For example, step 202 includes: performing rotation processing on the sample chip layout to obtain a rotary chip layout, and using the rotary chip layout as the at least one reference chip layout. It may be understood that the rotary chip layout herein may also be referred to as a sample chip layout obtained after rotation processing, which is briefly referred to as a rotated chip layout. In other words, the sample chip layout is rotated to obtain the rotated chip layout. The at least one reference chip layout includes the rotated chip layout. The following describes an implementation of rotation processing, and details are not described herein again.

In a possible implementation, step 202 includes: performing mirror flipping processing on the sample chip layout to obtain a symmetric chip layout; performing rotation processing on the sample chip layout and the symmetric chip layout to obtain a rotary chip layout; and using the symmetric chip layout and the rotary chip layout as the at least one reference chip layout. It may be understood that the symmetric chip layout herein may also be referred to as a sample chip layout obtained after mirror flipping processing, which is briefly referred to as a flipped chip layout. The rotary chip layout herein may also be referred to as a sample chip layout obtained after rotation processing and a symmetric chip layout obtained after rotation processing, which are briefly referred to as rotated chip layouts. In other words, mirror flipping is performed on the sample chip layout to obtain a flipped chip layout. The sample chip layout and the flipped chip layout are rotated to obtain a rotated chip layout. The at least one reference chip layout includes the flipped chip layout and the rotated chip layout.

In this embodiment of this application, mirror flipping processing may be performed on the sample chip layout based on mirror information, to implement flipping transformation on the sample chip layout, to obtain the symmetric chip layout, and use the symmetric chip layout as the reference chip layout. The mirror information may represent a position, an orientation, and the like of a mirror surface. The orientation of the mirror surface is the same as a normal direction of the mirror surface, and the position of the mirror surface is represented by a position of a reference point (such as a center point) in the mirror surface. When the mirror surface faces a horizontal direction, it indicates that the normal direction of the mirror surface is the horizontal direction. In this case, leftward or rightward mirror flipping processing may be performed on the sample chip layout. When the mirror surface faces a vertical direction, it indicates that the normal direction of the mirror surface is the vertical direction. In this case, upward or downward mirror flipping processing may be performed on the sample chip layout.

It may be understood that there is at least one piece of mirror information. For any piece of mirror information, mirror flipping processing is performed on the sample chip layout based on the mirror information to obtain one symmetric chip layout, and the symmetric chip layout is used as the reference chip layout. In this manner, different reference chip layouts may be determined based on different mirror information, so that there is at least one reference chip layout.

At least one time of rotation processing may be performed on the sample chip layout based on a rotation parameter, to implement rotation transformation on the sample chip layout to obtain a rotary chip layout obtained after each time of rotation processing. In other words, the first time of rotation processing may be performed on the sample chip layout based on the rotation parameter, and a sample chip layout obtained after the first time of rotation processing is used as a rotary chip layout obtained after the first time of rotation processing. Then, the second time of rotation processing is performed, based on the rotation parameter, on the rotary chip layout obtained after the first time of rotation processing, to obtain a rotary chip layout obtained after the second time of rotation processing. Subsequently, the third time of rotation processing is performed, based on the rotation parameter, on the rotary chip layout obtained after the second time of rotation processing, to obtain a rotary chip layout obtained after the third time of rotation processing. By analogy, at least one time of rotation processing is implemented on the sample chip layout.

Similarly, at least one time of rotation processing may be performed on the symmetric chip layout based on a rotation parameter, to implement rotation transformation on the symmetric chip layout to obtain a rotary chip layout obtained after each time of rotation processing. The rotary chip layout obtained after each time of rotation processing may be used as each reference chip layout. The rotation parameter is configured for indicating an angle by which rotation needs to be performed in each time of rotation processing. For example, the rotation parameter is a target angle by which rotation needs to be performed in each time of rotation processing. In this case, one rotary chip layout may be obtained after the sample chip layout is rotated once by the target angle, and one rotary chip layout may also be obtained after the symmetric chip layout is rotated once by the target angle.

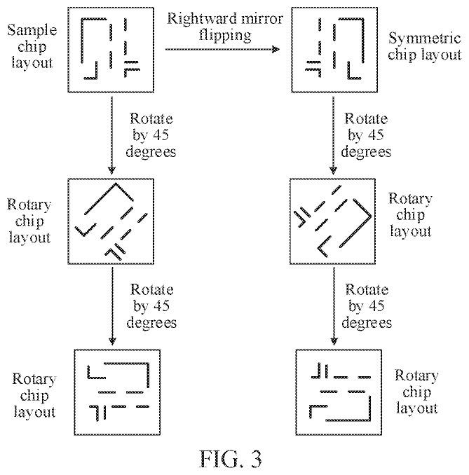

FIG. 3 is a schematic diagram of performing geometric transformation on a sample chip layout according to an embodiment of this application. In this embodiment of this application, two rotary chip layouts may be obtained after the sample chip layout is rotated once by 45 degrees. In addition, rightward mirror flipping processing may be first performed on the sample chip layout to obtain a symmetric chip layout, and then two rotary chip layouts are obtained after the symmetric chip layout is rotated once by 45 degrees.

In this embodiment of this application, the symmetric chip layout and the rotary chip layout may be used as reference chip layouts. It may be understood that rotation processing may be first performed on the sample chip layout to obtain a rotary chip layout, and then mirror flipping processing is performed on the sample chip layout and the rotary chip layout to obtain a symmetric chip layout. Subsequently, the symmetric chip layout and the rotary chip layout are used as reference chip layouts, and there is at least one reference chip layout. It may be understood that the rotary chip layout herein may also be referred to as a sample chip layout obtained after rotation processing, which is briefly referred to as a rotated chip layout. The symmetric chip layout herein may also be referred to as a sample chip layout obtained after mirror flipping processing and a rotary chip layout obtained after mirror flipping processing, which are briefly referred to as rotated chip layouts. In other words, the sample chip layout is rotated to obtain a rotated chip layout. Mirror flipping is performed on the sample chip layout and the rotated chip layout to obtain a flipped chip layout. The at least one reference chip layout includes the rotated chip layout and the flipped chip layout. The foregoing describes implementations of rotation processing and mirror flipping processing, and details are not described herein again.

In this embodiment of this application, performing mirror flipping processing on a chip layout (for example, the sample chip layout, the symmetric chip layout, and the rotary chip layout that are mentioned above) means: adjusting position information of each pixel in the chip layout based on mirror information, so that adjusted position information of any pixel and position information of the pixel meet mirror symmetry. A symmetric chip layout obtained after mirror flipping processing includes adjusted position information of each pixel.

Based on the same principle, performing rotation processing on a chip layout means: adjusting position information of each pixel in the chip layout based on a rotation parameter, so that adjusted position information of any pixel and position information of the pixel meet rotation transformation. A rotary chip layout obtained after rotation processing includes adjusted position information of each pixel.

Therefore, it may be learned that performing geometric transformation on the sample chip layout is adjusting position information of each pixel in the sample chip layout. The reference chip layout includes adjusted position information of each pixel. It may be understood that a neighbor relationship between pixels in the sample chip layout is the same as a neighbor relationship between pixels in the reference chip layout, and the neighbor relationship between pixels is a relationship indicating whether every two pixels are adjacent to each other. In other words, if two pixels in the sample chip layout are adjacent to each other, the two pixels in the reference chip layout are also adjacent to each other.

In this embodiment of this application, mirror flipping processing and rotation processing may be performed on the sample chip layout to obtain the reference chip layout, or rotation processing may be performed on the symmetric chip layout to obtain the reference chip layout, or mirror flipping processing may be performed on the rotary chip layout to obtain the reference chip layout. The reference chip layout is determined in a plurality of manners, so that diversity of the reference chip layout is improved. Therefore, the chip layout encoder obtained through training by using the reference chip layout has a strong generalization capability, and a representation capability of a layout feature can be improved, so that accuracy of a clustering result can be improved when clustering is performed on chip layouts based on the layout feature.

Step 203: Extract a sample layout feature of the sample chip layout and a reference layout feature of each reference chip layout by using the initial encoder.

In some embodiments, the sample layout feature may be referred to as a layout feature of the sample chip layout, and the reference layout feature may be referred to as a layout feature of the reference chip layout. Extracting the layout feature by using the initial encoder is equivalent to extracting the layout feature via the initial encoder. In this case, step 203 may be described as follows: extracting the layout feature of the sample chip layout and the layout feature of each reference chip layout via the initial encoder.

The sample chip layout may be inputted into the initial encoder, and the initial encoder performs feature extraction on the sample chip layout to obtain the layout feature of the sample chip layout. Similarly, for any reference chip layout, the reference chip layout may be inputted into the initial encoder, and the initial encoder performs feature extraction on the reference chip layout to obtain a layout feature of the reference chip layout. The following focuses on a manner in which the initial encoder performs feature extraction on the sample chip layout. A manner in which the initial encoder performs feature extraction on the reference chip layout is similar to the manner in which the initial encoder performs feature extraction on the sample chip layout, and details are not described below.

In a possible implementation, “extracting a layout feature of the sample chip layout by using the initial encoder” in step 203 includes: performing a plurality of times of downsampling processing on the sample chip layout via the initial encoder (that is, by using the initial encoder), to obtain each downsampling feature. Each downsampling feature is a downsampling feature obtained through each time of downsampling processing, and the layout feature, namely, the sample layout feature, of the sample chip layout is a downsampling feature obtained through the last time of downsampling processing.

In this embodiment of this application, the initial encoder includes at least two convolutional blocks, and input of a current convolutional block is output of a previous convolutional block. Based on this, the sample chip layout is inputted into the initial encoder, a plurality of times of downsampling processing are performed by using the at least two convolutional blocks, and output of each convolutional block is a downsampling feature. In some embodiments, compared with input of each convolutional block, a feature size of output of the convolutional block is reduced by half, and a channel quantity thereof doubles. Final output of the initial encoder may be a one-dimensional feature vector, for example, a dimension of the one-dimensional feature vector is (1, 1, 1024). The one-dimensional feature vector is the layout feature of the sample chip layout.

In an exemplary embodiment, “performing a plurality of times of downsampling processing on the sample chip layout by using the initial encoder, to obtain each downsampling feature” includes: performing the first time of downsampling processing on the sample chip layout by using the initial encoder, to obtain a first downsampling feature; and performing, for any downsampling feature obtained through any time of downsampling processing, a next time of downsampling processing on the any downsampling feature by using the initial encoder, to obtain a downsampling feature obtained through the next time of downsampling processing.

In other words, after the sample chip layout is inputted into the initial encoder, the initial encoder may map the sample chip layout into an initial feature, and perform downsampling processing on the initial feature of the sample chip layout by using the first convolutional block in the at least two convolutional blocks, to obtain the first downsampling feature. Then, downsampling processing is performed on the first downsampling feature by using the second convolutional block in the at least two convolutional blocks, to obtain the second downsampling feature, and so on. The process continues until the last downsampling feature is obtained, and the last downsampling feature is the layout feature of the sample chip layout.

In other words, after the sample chip layout is inputted into the initial encoder, downsampling processing is performed, by using the first convolutional block in the at least two convolutional blocks, on the initial feature obtained by mapping the sample chip layout, to obtain the first downsampling feature. For an i^{th} convolutional block (i is a positive integer greater than 1), downsampling processing is performed on an (i−1)^{th} downsampling feature by using the i^{th} convolutional block, to obtain an i^{th} downsampling feature. It is assumed that there are M convolutional blocks in total. In this case, an M^{th} downsampling feature obtained by using an M^{th} convolutional block is the layout feature of the sample chip layout.

A plurality of times of downsampling processing are performed on the sample chip layout, so that a dimension of the downsampling feature is continuously reduced, and a representation capability of the downsampling feature is improved, that is, a representation capability of the layout feature of the sample chip layout is improved.

In some embodiments, one convolutional block includes one convolutional layer, the convolutional layer includes at least one 3×3 filter, and a quantity of filters included in a previous convolutional block is less than a quantity of filters included in a current convolutional block. The convolution layer is configured for performing convolution processing on the initial feature of the sample chip layout or the downsampling feature to obtain a convolved feature. If the convolutional block includes only the convolutional layer, the convolution processing is equivalent to downsampling processing, and the convolved feature is equivalent to a downsampling feature.

In some embodiments, one convolutional block includes a convolutional layer and a batch normalization layer that are connected in series. The batch normalization layer is configured for performing batch normalization processing on a convolved feature to obtain a batch normalization feature. If the convolutional block includes only the convolutional layer and the batch normalization layer, the downsampling processing includes convolution processing and batch normalization processing, and the batch normalization feature is equivalent to a downsampling feature.

In some embodiments, one convolutional block includes a convolutional layer, a batch normalization layer, and an activation layer that are connected in series. The activation layer is configured for performing activation processing on a batch normalization feature to obtain an activation feature. If the convolutional block includes only the convolutional layer, the batch normalization layer, and the activation layer, the downsampling processing includes convolution processing, batch normalization processing, and activation processing, and the activation feature is equivalent to a downsampling feature. The activation layer may use a rectified linear unit (ReLU), and the rectified linear unit is also referred to as a rectified linear unit.

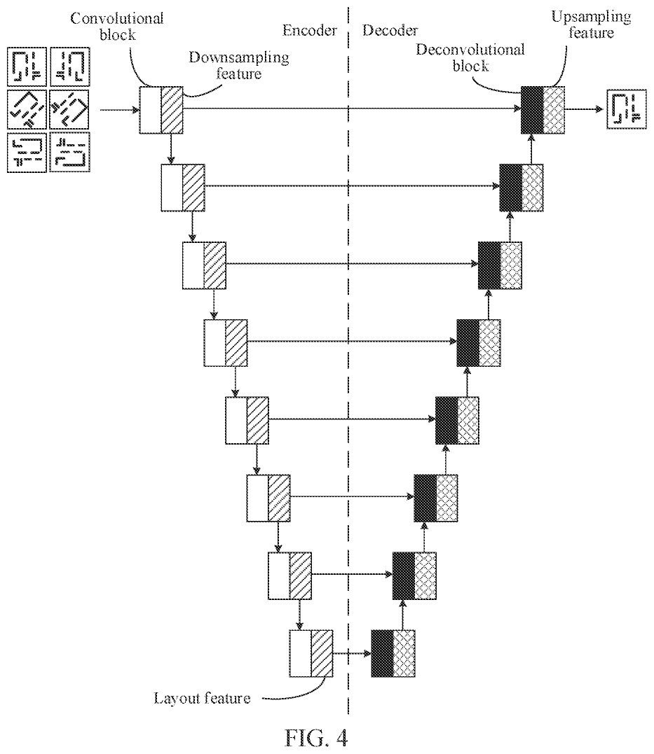

FIG. 4 is a schematic diagram of a Unet framework according to an embodiment of this application. The Unet framework includes an encoder, and the encoder is the initial encoder in this embodiment of this application. The encoder includes eight convolutional blocks, and each convolutional block includes a convolutional layer, a batch normalization layer, and an activation layer that are connected in series, and the activation layer uses a rectified linear unit. The eight convolutional blocks successively include 8, 16, 32, 64, 128, 256, 512, and 1024 3×3 filters.

FIG. 4 shows the sample chip layout, the symmetric chip layout, and the rotary chip layout that are shown in FIG. 3. These layouts are all inputted into the Unet framework, and layout features of these layouts are extracted by the encoder included in the Unet framework.

The sample chip layout is used as an example. The sample chip layout is inputted into the Unet framework, and the encoder included in the Unet framework performs eight times of downsampling processing on the sample chip layout to obtain eight downsampling features. It is assumed that a size of the sample chip layout is (256, 256, 1). In this case, sizes of the eight downsampling features are respectively (128, 128, 8), (64, 64, 16), (32, 32, 32), (16, 16, 64), (8, 8, 128), (4, 4, 256), and (1, 1, 1024). The last downsampling feature is the layout feature of the sample chip layout. Therefore, a size of the layout feature of the sample chip layout is (1, 1, 1024), and is a one-dimensional feature vector.

Step 204: Train the initial encoder based on the sample layout feature and the reference layout feature to obtain a trained encoder.

It may be understood that the trained encoder may also be referred to as a chip layout encoder. Based on this, step 204 may be described as follows: training the initial encoder based on the layout feature of the sample chip layout and the layout feature of each reference chip layout to obtain a chip layout encoder.

In some embodiments, the trained encoder is configured to generate a chip layout and/or extracting a feature of a chip layout.

In this embodiment of this application, a first loss may be determined based on the layout feature of the sample chip layout and the layout feature of each reference chip layout. In some embodiments, for any reference chip layout, a distance between the layout feature of the reference chip layout and the layout feature of the sample chip layout may be calculated, the distance is referred to as a distance corresponding to the reference chip layout, weighted calculation (for example, weighted summation and weighted averaging) is performed on distances corresponding to the reference chip layouts, and a weighted calculation result is used as the first loss. Alternatively, averaging calculation may be performed on the layout features of the reference chip layouts to obtain an average layout feature, a distance between the average layout feature and the layout feature of the sample chip layout is calculated, and the distance is used as the first loss.

For example, averaging calculation may be performed on the layout features of the reference chip layouts by using the following Formula (1), to obtain the average layout feature:

$$\overline{Encoder ( \hat{T} {x}_{1} )} = \frac{1}{K} {\sum }_{n}^{K} Encoder ( ) \qquad Formula ( 1 )$$

where xⁱ represents an i^{th} sample chip layout, [symbol] represents a reference chip layout obtained after an nth time of geometric transformation is performed on the i^{th} sample chip layout, and K represents a total quantity of times of geometric transformation, and also represents a quantity of reference chip layouts. For one sample chip layout, performing one time of mirror flipping processing on the sample chip layout and a rotary chip layout is equivalent to performing one time of geometric transformation on the sample chip layout to obtain a symmetric chip layout. Rotating the sample chip layout, the symmetric chip layout, and the rotary chip layout by the target angle is equivalent to performing one time of geometric transformation on the sample chip layout to obtain a rotary chip layout. If one time of leftward mirror flipping processing and one time of rightward mirror flipping processing are performed on one sample chip layout to obtain two symmetric chip layouts, and the two symmetric chip layouts are rotated once by 45 degrees, a total quantity of times of rotation is 14, and 14 rotary chip layouts may be obtained. Both the symmetric chip layouts and the rotary chip layouts are used as reference chip layouts. Therefore, a quantity of reference chip layouts is 16, and a value of K is 16.

In addition, in Formula (1), Encoder represents a feature extraction operation, and Σ represents a symbol of a summation function. Therefore, E̅n̅c̅o̅d̅e̅r̅(̅T̅x̅ᵢ̅)̅ represents the average layout feature, and Encoder( [symbol] ) represents a layout feature of the reference chip layout obtained after the nth time of geometric transformation is performed on the i^{th} sample chip layout.

Based on Formula (1), the distance between the average layout feature and the layout feature of the sample chip layout may be calculated by using the following Formula (2), to obtain the first loss:

$${Loss}_{r o t a t i o n} = {\sum }_{i = 0}^{N} {\vert Encoder ( {x}_{i} ) - \overline{Encoder ( )} \vert}^{2} \qquad Formula ( 2 )$$

where Lossᵣₒₜₐₜᵢₒₙ represents the first loss, Encoder(xᵢ) represents a layout feature of the i^{th} sample chip layout, a total quantity of sample chip layouts is N+1, and Σ represents a symbol of a summation function.

After the first loss is calculated, the first loss may be used as a loss of the initial encoder, and the initial encoder is trained by using the loss of the initial encoder in a gradient descent manner to obtain the trained initial encoder. Training the initial encoder is adjusting a weight and a bias of a neuron in the initial encoder, to reduce the loss of the initial encoder. If the trained initial encoder meets a training end condition, the trained initial encoder is used as the chip layout encoder (namely, the trained encoder). If the trained initial encoder does not meet the training end condition, the trained initial encoder is used as an initial encoder in a next time training, and the next time of training is performed on the initial encoder based on the method for training a chip layout encoder provided in this embodiment of this application, until the chip layout encoder is obtained.

That the training end condition is met is not limited in this embodiment of this application. For example, that the training end condition is met is that a quantity of times of training reaches a target quantity (for example, 500 times). Alternatively, when the initial encoder is trained by using the loss of the initial encoder in a gradient descent manner, a gradient of the loss of the initial encoder needs to be determined, and a parameter of the initial encoder is adjusted based on the gradient, so that a gradient that is of a loss of an initial encoder determined and that is in a next time of training is less than the gradient that is of the loss of the initial encoder and that is determined in the current time of training. When a gradient difference between the gradient that is of the loss of the initial encoder and that is determined in the next time of training and the gradient that is of the loss of the initial encoder and that is determined in the current time of training is less than a difference threshold, it is determined that the training end condition is met. In other words, the gradient that is of the loss of the initial encoder and that is determined in the next time of training is subtracted from the gradient that is of the loss of the initial encoder and that is determined in the current time of training, to obtain the gradient difference. If the gradient difference is less than the difference threshold, the training end condition is met. In this case, that the training end condition is met is equivalent to that a descent range of the gradient of the loss of the initial encoder falls within a range of the difference threshold. A manner of determining the difference threshold is not limited in this embodiment of this application. For example, the difference threshold is determined based on manual experience, or a data range is manually set, and the difference threshold is randomly generated data falling within the data range.

Because the first loss is determined based on the layout feature of the sample chip layout and the layout feature of each reference chip layout, the initial encoder may be trained by using the first loss, so that the layout feature of the sample chip layout and the layout feature of the reference chip layout that are extracted by the initial encoder are close to each other. Because the reference chip layout is obtained by performing geometric transformation on the sample chip layout, the reference chip layout and the sample chip layout belong to the same type of chip layout. In a process of training the initial encoder, a layout feature extracted by the initial encoder may continuously tend to represent a chip layout category, so that a finally trained chip layout encoder focuses on extracting a layout feature that can represent a chip layout category. The layout feature extracted by the chip layout encoder may represent a chip layout before geometric transformation and a chip layout after geometric transformation, so that the layout feature extracted by the chip layout encoder has a property of invariance before and after geometric transformation. Therefore, the first loss is a loss that may represent invariance before and after geometric transformation.

In a possible implementation, the method for training a chip layout encoder further includes step 205. Step 205 is performed after step 203.

Step 205: Determine a reconstructed chip layout based on the layout feature of the sample chip layout. That is, the reconstructed chip layout is determined based on the sample layout feature, and the reconstructed chip layout is a chip layout reconstructed based on the layout feature of the sample chip layout.

In this embodiment of this application, the layout feature of the sample chip layout may be inputted into the initial decoder, and a new chip layout is reconstructed by the initial decoder based on the layout feature of the sample chip layout, to obtain the reconstructed chip layout. In this embodiment of this application, a structure, a size, and the like of the initial decoder are not limited. For example, the initial decoder is a decoder in the Unet framework.

In a possible implementation, step 205 includes: performing a plurality of times of upsampling processing on the layout feature of the sample chip layout to obtain each upsampling feature, each upsampling feature being an upsampling feature obtained through each time of upsampling processing; or performing a plurality of times of upsampling processing on the sample layout feature to obtain an upsampling feature obtained through each time of upsampling processing, the reconstructed chip layout being a chip layout obtained based on an upsampling feature obtained through the last time of upsampling processing.

In this embodiment of this application, the initial decoder includes at least two deconvolutional blocks, and output of a previous deconvolutional block is input of a current deconvolutional block. In some embodiments, compared with input of each deconvolutional block, a feature size of output of the deconvolutional block doubles, and a quantity of channels thereof is reduced by half. A feature size finally outputted by the initial decoder is consistent with the size of the sample chip layout inputted into the initial encoder.

In other words, after the layout feature of the sample chip layout is inputted into the initial decoder, upsampling processing is performed on the layout feature of the sample chip layout by using the first deconvolutional block in the at least two deconvolutional blocks, to obtain a first upsampling feature. Then, upsampling processing is performed on the first upsampling feature by using the second deconvolutional block in the at least two deconvolutional blocks, to obtain the second upsampling feature, and so on. The process continues until the last upsampling feature is obtained, the last upsampling feature may be mapped into a chip layout, and the chip layout is the reconstructed chip layout.

In other words, after the layout feature of the sample chip layout is inputted into the initial decoder, upsampling processing is performed on the layout feature of the sample chip layout by using the first deconvolutional block in the at least two deconvolutional blocks, to obtain the first upsampling feature. For an i^{th} deconvolutional block (i is a positive integer greater than 1), upsampling processing is performed on an (i−1)^{th} upsampling feature by using the i^{th} deconvolutional block, to obtain an i^{th} upsampling feature. It is assumed that there are M deconvolutional blocks in total. In this case, an M^{th} upsampling feature obtained by using an M^{th} deconvolutional block may be mapped into the reconstructed chip layout.

In some embodiments, one deconvolutional block includes one deconvolutional layer, the deconvolutional layer includes at least one 3×3 filter, and a quantity of filters included in a previous deconvolutional block is greater than a quantity of filters included in a current deconvolutional block. The deconvolution layer is configured for performing deconvolution processing on the layout feature of the sample chip layout or the upsampling feature to obtain a deconvolved feature. If the deconvolutional block includes only the deconvolutional layer, the deconvolution processing is equivalent to upsampling processing, and the deconvolved feature is equivalent to an upsampling feature.

In some embodiments, one deconvolutional block includes a deconvolutional layer and a batch normalization layer that are connected in series. The batch normalization layer is configured for performing batch normalization processing on a deconvolved feature to obtain a batch normalization feature. If the deconvolutional block includes only the deconvolutional layer and the batch normalization layer, the upsampling processing includes deconvolution processing and batch normalization processing, and the batch normalization feature is equivalent to an upsampling feature.

In some embodiments, one deconvolutional block includes a deconvolutional layer, a batch normalization layer, and an activation layer that are connected in series. The activation layer is configured for performing activation processing on a batch normalization feature to obtain an activation feature. If the deconvolutional block includes only the deconvolutional layer, the batch normalization layer, and the activation layer, the upsampling processing includes deconvolution processing, batch normalization processing, and activation processing, and the activation feature is equivalent to an upsampling feature. The activation layer may use a Leaky-ReLU activation function or a sigmoid activation function.

In some embodiments, the performing a plurality of times of upsampling processing on the layout feature of the sample chip layout to obtain each upsampling feature includes step A1 to step A4 that are shown below:

Step A1: Perform the first time of upsampling processing on the layout feature (namely, the sample layout feature) of the sample chip layout to obtain a first upsampling feature, the layout feature (namely, the sample layout feature) of the sample chip layout being obtained by performing a plurality of times of downsampling processing on the sample chip layout.

In step 203, content that a plurality of times of downsampling processing are performed on the sample chip layout to obtain the layout feature of the sample chip layout has been mentioned, and details are not described herein again. In this embodiment of this application, after the layout feature of the sample chip layout is inputted into the initial decoder, upsampling processing is performed on the layout feature of the sample chip layout by using the first deconvolutional block in the at least two deconvolutional blocks, to obtain the first upsampling feature.

Step A2: Obtain, for any upsampling feature obtained through any time of upsampling processing, a downsampling feature corresponding to the any upsampling feature, a quantity of times of downsampling processing when downsampling processing is performed on the sample chip layout to obtain the downsampling feature corresponding to the any upsampling feature being a first quantity of times, a quantity of times of upsampling processing when upsampling processing is performed on the layout feature (namely, the sample layout feature) of the sample chip layout to obtain the any upsampling feature being a second quantity of times, and a sum of the first quantity of times and the second quantity of times being a target quantity of times.

In this embodiment of this application, a quantity of convolutional blocks in the initial encoder is the same as a quantity of deconvolutional blocks in the initial decoder. Therefore, a total quantity of times that the initial encoder performs downsampling processing is the same as a total quantity of times that the initial decoder performs upsampling processing. The target quantity of times is the total quantity of times that the initial encoder performs downsampling processing. For example, if the initial encoder performs eight times of downsampling processing in total, the target quantity of times is 8.

For an i^{th} upsampling feature (i is a positive integer greater than or equal to 1) obtained through an i^{th} time of upsampling processing, the second quantity of times is i. The sum of the first quantity of times and the second quantity of times is the target quantity of times. Therefore, if the target quantity of times is M, the first quantity of times is M−i. It may be determined that a downsampling feature corresponding to the i^{th} upsampling feature is: an (M−i)^{th} downsampling feature obtained by performing an (M−i)^{th} time of downsampling processing on the sample chip layout.

For example, if the target quantity of times is 8, a downsampling feature corresponding to the first upsampling feature is the seventh downsampling feature, a downsampling feature corresponding to the second upsampling feature is the sixth downsampling feature, and so on.

Step A3: Splice the any upsampling feature with the downsampling feature corresponding to the any upsampling feature, to obtain a spliced feature corresponding to the any upsampling feature.

The i^{th} upsampling feature may be spliced with the (M−i)^{th} downsampling feature to obtain a spliced feature corresponding to the i^{th} upsampling feature.

Step A4: Perform upsampling processing on the spliced feature corresponding to the any upsampling feature, to obtain a next upsampling feature of the any upsampling feature.

Upsampling processing is performed on the spliced feature corresponding to the i^{th} upsampling feature, to obtain an (i+1)^{th} upsampling feature.

When the last upsampling feature is obtained, the last upsampling feature may be mapped into the reconstructed chip layout, or the last upsampling feature and the first downsampling feature may be spliced to obtain a spliced feature corresponding to the last upsampling feature, and the spliced feature corresponding to the last upsampling feature is mapped into the reconstructed chip layout.

Referring to FIG. 4, the Unet framework shown in FIG. 4 includes a decoder, and the decoder is the initial decoder in this embodiment of this application. The decoder includes eight deconvolutional blocks, and each deconvolutional block includes a deconvolutional layer, a batch normalization layer, and an activation layer that are connected in series. The eight deconvolutional blocks successively include 1024 3×3 filters, 512 3×3 filters, 256 3×3 filters, 128 3×3 filters, 64 3×3 filters, 32 3×3 filters, 16 3×3 filters, and 1 3×3 filter. Activation layers in the first seven deconvolutional blocks are Leaky-ReLU activation functions, and an activation layer in the eighth deconvolutional block is a sigmoid activation function. The encoder in the Unet framework has been described above, and details are not described herein again.

In this embodiment of this application, the encoder in the Unet framework may perform eight times of downsampling processing on the sample chip layout, to obtain eight downsampling features; perform upsampling processing on the eighth downsampling feature to obtain the first upsampling feature; obtain the second upsampling feature based on the first upsampling feature and the seventh downsampling feature; obtain the third upsampling feature based on the second upsampling feature and the sixth downsampling feature, and so on, until the eighth upsampling feature is obtained based on the seventh upsampling feature and the first downsampling feature.

When the second upsampling feature is obtained based on the first upsampling feature and the seventh downsampling feature, the first upsampling feature may be spliced with the seventh downsampling feature to obtain a spliced feature corresponding to the first upsampling feature, and upsampling processing is performed on the spliced feature corresponding to the first upsampling feature, to obtain the second upsampling feature. Manners of determining the third upsampling feature to the eighth upsampling feature are similar to the manner of determining the second upsampling feature, and details are not described herein again.

It is assumed that the size of the layout feature of the sample chip layout is (1, 1, 1024), and is a one-dimensional feature vector. In this case, sizes of the eight upsampling features are successively (2, 2, 1024), (4, 4, 512), (8, 8, 256), (16, 16, 128), (32, 32, 64), (64, 64, 32), (128, 128, 16), and (256, 256, 1). A size of the reconstructed chip layout obtained based on the eighth upsampling feature is (256, 256, 1), and is consistent with the size of the sample chip layout.

In this embodiment of this application, determining a next upsampling feature of any upsampling feature based on the upsampling feature and a downsampling feature corresponding to the upsampling feature is essentially splicing output of a convolutional block in the initial encoder with output of a deconvolutional block in the initial decoder together as input of a next deconvolutional block. This can improve a representation capability of an upsampling feature obtained after upsampling processing is performed by using the deconvolutional block, thereby improving accuracy of the reconstructed chip layout, and making the reconstructed chip layout close to the sample chip layout.

In some embodiments, the reconstructed chip layout outputted by the initial decoder is a binary mask layout. The binary mask map includes a plurality of pixels, and a value of each pixel indicates that the pixel is transparent or opaque. In some embodiments, if a value of a pixel is a first value, it indicates that the pixel is transparent; or if a value of a pixel is a second value, it indicates that the pixel is opaque. The first value is any value, for example, the first value is 0. The second value is any value different from the first value, for example, the second value is 1. In other words, if the first value is 0 and the second value is 1, when a value of a pixel on the binary mask map is 1, it indicates that the pixel is opaque; or when a value of a pixel on the binary mask map is 0, it represents that the pixel is transparent.

When the reconstructed chip layout may be obtained, step 204 includes: training the initial encoder based on the sample chip layout, the reconstructed chip layout, the layout feature (namely, the sample layout feature) of the sample chip layout, and the layout feature (namely, the reference layout feature) of each reference chip layout, to obtain the chip layout encoder (namely, the trained encoder).

A loss of the initial encoder may be determined based on the sample chip layout, the reconstructed chip layout, the layout feature of the sample chip layout, and the layout feature of each reference chip layout. The initial encoder is trained by using the loss of the initial encoder to obtain the chip layout encoder.

In some embodiments, the training the initial encoder based on the sample chip layout, the reconstructed chip layout, the layout feature of the sample chip layout, and the layout feature of each reference chip layout, to obtain the chip layout encoder includes the following steps B1 to B3.

Step B1: Determine a first loss based on the layout feature (namely, the sample layout feature) of the sample chip layout and the layout feature (namely, the reference layout feature) of each reference chip layout. A process of determining the first loss has been described in step 204, and details are not described herein again.

Step B2: Determine a second loss based on the sample chip layout and the reconstructed chip layout.

In this embodiment of this application, a distance between the sample chip layout and the reconstructed chip layout may be obtained by comparing the sample chip layout with the reconstructed chip layout at a pixel level, and the distance is used as the second loss.

In some embodiments, the second loss is determined by using the following Formula (3):

$${Loss}_{r e b u i l d} = {\sum }_{i = 0}^{N} {\vert {x}_{i} - {x}_{i ( p r e d )} \vert}^{2} \qquad Formula ( 3 )$$

where Loss_{rebuild} represents the second loss, xᵢ represents an i^{th} sample chip layout, xᵢ(pred) represents a reconstructed chip layout corresponding to the i^{th} sample chip layout, a total quantity of sample chip layouts is N+1, and 2 represents a symbol of a summation function.

Step B3: Train the initial encoder based on the first loss and the second loss to obtain the chip layout encoder (namely, the trained encoder).

In this embodiment of this application, operation processing such as summation, weighted summation, averaging, and weighted averaging may be performed on the first loss and the second loss, and an operation processing result is determined as the loss of the initial encoder, for example, the loss of the initial encoder is Loss=Loss_{rebuild}+Lossᵣₒₜₐₜᵢₒₙ. The initial encoder is trained by using the loss of the initial encoder to obtain the chip layout encoder.

Because the second loss is determined based on the sample chip layout and the reconstructed chip layout, the initial encoder is trained by using the second loss. In this way, after the layout feature of the sample chip layout is extracted via the initial encoder, the reconstructed chip layout that is closer to the sample chip layout can be reconstructed via the initial decoder based on the layout feature of the sample chip layout, thereby ensuring that the layout feature of the sample chip layout can accurately represent the sample chip layout, and improving accuracy of the layout feature of the sample chip layout.

In a process of training the initial encoder by using the loss of the initial encoder, the initial decoder may also be synchronously trained by using the loss of the initial encoder, to improve a training effect. During application, a re-established chip layout may be determined based on the layout feature of the reference chip layout. The re-established chip layout is a chip layout reconstructed based on the layout feature of the reference chip layout. A third loss is determined by using the reference chip layout and the re-established chip layout. A loss of the initial encoder is determined by using at least one of the first loss, the second loss, and the third loss, to train the initial encoder by using the loss of the initial encoder, to obtain the chip layout encoder. A manner of determining the re-established chip layout is similar to a manner of determining the reconstructed chip layout, and a manner of determining the third loss is similar to a manner of determining the second loss. Details are not described herein again.

Information (including but not limited to user device information, user personal information, and the like), data (including but not limited to data used for analysis, stored data, and displayed data), and a signal in this application are authorized by a user or fully authorized by each party, and related data needs to be collected, used, and processed in compliance with relevant national laws and standards. For example, the sample chip layout in this application is obtained in case of full authorization.

According to the foregoing method, geometric transformation is performed on the sample chip layout to obtain the reference chip layout, and the initial encoder is trained by using the layout feature of the sample chip layout and the layout feature of the reference chip layout to obtain the chip layout encoder. Therefore, the chip layout encoder can output similar layout features for chip layouts before and after geometric transformation. The chip layouts before and after geometric transformation belong to the same chip layout type. Therefore, the chip layout encoder focuses on extracting a layout feature that can distinguish between chip layout types. This helps improve accuracy of a clustering result and reduces redundancy of a screening result when clustering and screening processing are subsequently performed on chip layouts based on the layout feature.

An embodiment of this application further provides a chip layout screening method. The method may be applied to the foregoing implementation environment, so that a key chip layout can be accurately obtained from a plurality of target chip layouts through screening. A flowchart of a chip layout screening method according to an embodiment of this application shown in FIG. 5 is used as an example. For ease of description, the terminal device 101 or the server 102 that performs the chip layout screening method in this embodiment of this application is referred to as an electronic device. The method may be performed by the electronic device. As shown in FIG. 5, the method includes the following steps:

Step 501: Obtain a plurality of target chip layouts and a trained encoder.

The trained encoder may also be referred to as a chip layout encoder. Step 501 may be described as follows: obtaining a plurality of target chip layouts and a chip layout encoder.

In this embodiment of this application, any target chip layout is an IC layout or a sub-area obtained by dividing the IC layout. A manner of determining the target chip layout is the same as a manner of determining a sample chip layout. For details, refer to descriptions of step 201. Details are not described herein again. The chip layout encoder is obtained through training based on the method for training a chip layout encoder related to FIG. 2. For details, refer to related descriptions of step 201 to step 205. Details are not described herein again.

Step 502: Extract target layout features of the target chip layouts by using the trained encoder.

The target layout feature may also be referred to as a layout feature of the target chip layout. Step 502 may also be described as follows: extracting layout features of the target chip layouts by using the chip layout encoder.

Any target chip layout is inputted into the chip layout encoder, and the chip layout encoder performs feature extraction on the target chip layout to obtain a layout feature of the target chip layout. A manner of determining the layout feature of the target chip layout is similar to a manner of determining a layout feature of the sample chip layout. For details, refer to related descriptions of step 203. Details are not described herein again.

Step 503: Perform clustering on the plurality of target chip layouts based on the target layout features, to obtain a plurality of target clusters, any target cluster including at least one target chip layout.

The layout feature of the target chip layout may represent the target chip layout. The layout features of the target chip layouts are calculated, so that the plurality of target chip layouts can be clustered into a plurality of target clusters.

For example, for any two target chip layouts, a distance between layout features of the two target chip layouts may be calculated according to a distance formula. If the distance between the layout features of the two target chip layouts is less than a distance threshold, it indicates that the two target chip layouts are similar, and the two target chip layouts are clustered into the same initial cluster. If the distance between the layout features of the two target chip layouts is not less than the distance threshold, it indicates that the two target chip layouts are dissimilar, and the two target chip layouts are clustered into different initial clusters. In this manner, the plurality of target chip layouts may be clustered into a plurality of initial clusters, and each initial cluster includes at least one target chip layout. In some embodiments, each initial cluster is used as each target cluster, thereby clustering the plurality of target chip layouts into a plurality of target clusters. The distance formula is not limited in this embodiment of this application. For example, the distance formula is a formula of a Euclidean spatial distance or a formula of a cosine distance. A value of the distance threshold may be set based on experience.

In a possible implementation, step 503 includes step 5031 to step 5034.

Step 5031: Obtain a plurality of first layout features, one first layout feature being configured for representing a clustering center of one first cluster.

A manner in which the electronic device obtains the first layout feature is not limited in this embodiment of this application. For example, the plurality of first layout features may be configured on the electronic device. Alternatively, a user may input the plurality of first layout features into the electronic device. Alternatively, the electronic device may cluster the plurality of target chip layouts into a plurality of initial clusters, average, for any initial cluster, layout feature of target chip layouts included in the initial cluster, and use an obtained result as one first layout feature. In this case, a quantity of first layout features is the same as a quantity of initial clusters. Alternatively, in a manner of step 5031 to step 5038, a plurality of times of clustering are performed on the plurality of target chip layouts, a plurality of clusters are obtained after the last time of clustering in the plurality of times of clustering, layout features of target chip layouts included in the clusters are averaged, and obtained results are used as first layout features. One first layout feature is an expected clustering center of one first cluster, and may represent a clustering center of the first cluster.

Step 5032: Calculate distances between the layout features (namely, the target layout features) of the target chip layouts and the first layout features. For example, a distance between a layout feature of any target chip layout and any first layout feature may be calculated according to the formula of the Euclidean spatial distance or the formula of the cosine distance.

Step 5033: Select, for any target chip layout, a minimum first distance from distances between a layout feature (namely, a target layout feature) of the any target chip layout and the first layout features, and cluster the any target chip layout into a first cluster corresponding to a first layout feature corresponding to the first distance.

In this embodiment of this application, a smaller distance between the layout feature of the target chip layout and the first layout feature indicates that the layout feature of the target chip layout is more similar to the first layout feature, and both the layout feature of the target chip layout and the first layout feature are more capable of representing the same type of chip layout. Based on this principle, the minimum first distance may be selected from the distances between the layout feature of the any target chip layout and the first layout features. The first layout feature corresponding to the first distance is a first layout feature that is in the first layout features and that is most similar to the layout feature of the target chip layout. The target chip layout may be clustered into the first cluster corresponding to the first layout feature corresponding to the first distance.

In this manner, the plurality of target chip layouts may be clustered into a plurality of first clusters. Target chip layouts in the same first cluster correspond to the same type of chip layout. Therefore, in this manner, the target chip layouts may be clustered based on types of the chip layouts.

Step 5034: Use each first cluster as each target cluster when each first cluster meets a clustering end condition.

That any first cluster meets the clustering end condition is not limited in this embodiment of this application. For example, that any first cluster meets the clustering end condition is as follows: A quantity of clustering times corresponding to the first cluster reaches a specified quantity of times. For example, if a quantity of clustering times corresponding to a first cluster is 50, and reaches the specified quantity of times, the first cluster meets the clustering end condition. The following further describes another implementation in which any first cluster meets the clustering end condition. Details are not described herein again.

In some embodiments, for any first cluster, an actual clustering center of the first cluster may be determined based on layout features of target chip layouts in the first cluster. For example, an averaging operation is performed on layout features of target chip layouts in an i^{th} first cluster according to the following Formula (4), to obtain an actual clustering center of the first cluster:

$${μ}_{i} = \frac{1}{\vert {C}_{i} \vert} {\sum }_{x ∈ {C}_{i}} x \qquad Formula ( 4 )$$

where μᵢ represents the actual clustering center of the i^{th} first cluster, Cᵢ represents a quantity of target chip layouts included in the i^{th} first cluster, X represents the layout feature of the target chip layout, and Σ is a function symbol of a summation function.

In a possible implementation, a first quantity of clustering times of clustering are performed on the plurality of target chip layouts, and first clusters are obtained after the last time of clustering in clustering of the first quantity of clustering times. In this case, clustering of a quantity of clustering times obtained by subtracting one from the first quantity of clustering times may be completed for the plurality of target chip layouts, and clusters are obtained after the last time of clustering in the clustering of the quantity of clustering times obtained by subtracting one from the first quantity of clustering times. In other words, M (M is a positive integer) times of clustering are performed on the plurality of target chip layouts, and the last time of clustering in the M times of clustering is referred to as an M^{th} time of clustering processing. In this case, first clusters are obtained after the M^{th} time of clustering processing, and clusters are obtained after an (M−1)^{th} time of clustering processing. In this embodiment of this application, an actual clustering center of each cluster may be obtained. If an error between the actual clustering center of each cluster and an actual clustering center of each first cluster falls within a specified range, it is determined that each first cluster meets the clustering end condition.

In another possible implementation, an error of any first cluster may be determined based on layout features of target chip layouts in the first cluster and an actual clustering center of the first cluster, and a total clustering error is obtained by determining a sum of errors of the first clusters. In some embodiments, according to the following Formula (5), a sum of squares of differences between layout features of target chip layouts in the first cluster and an actual clustering center of the first cluster is calculated, to obtain an error of the first cluster, and a sum of errors of the first clusters is used as a total clustering error:

$$Error = {\sum }_{i = 1}^{N} {\sum }_{x ∈ {C}_{i}} {\vert x - {μ}_{i} \vert}^{2} \qquad Formula ( 5 )$$

where Error represents the total clustering error, N represents a quantity of first clusters, μᵢ represents an actual cluster center of an i^{th} first cluster, Cᵢ represents a quantity of target chip layouts included in the i^{th} first cluster, X represents the layout feature of the target chip layout, and Σ is a function symbol of a summation function.

In a possible implementation, when a total clustering error of the first clusters is less than a specified total error, it is determined that each first cluster meets the clustering end condition. Alternatively, a first quantity of clustering times of clustering are performed on the plurality of target chip layouts, to obtain first clusters. In this case, a total clustering error of clusters obtained after clustering of a quantity of clustering times obtained by subtracting one from the first quantity of clustering times is performed on the target chip layouts may be obtained. If a difference between the total clustering error of the clusters and the total clustering error of the first clusters falls within a specified range, it is determined that each first cluster meets the clustering end condition.

When each first cluster meets the clustering end condition, each first cluster is used as each target cluster.

In some embodiments, after step 5033, the method further includes step 5035 to step 5038.

Step 5035: Determine, for any first cluster when each first cluster does not meet the clustering end condition, one second layout feature based on layout features of target chip layouts in the any first cluster, the one second layout feature being configured for representing a clustering center of one second cluster.

That each first cluster does not meet the clustering end condition is equivalent to that a first cluster that does not meet the clustering end condition exists in the plurality of first clusters. In this case, an actual clustering center of any first cluster may be determined based on layout features (namely, target layout features) of target chip layouts in the any first cluster, and the actual clustering center of the first cluster is used as one second layout feature. The second layout feature is an expected clustering center of one second cluster, and may represent a clustering center of the second cluster.

Step 5036: Calculate distances between the layout features (namely, the target layout features) of the target chip layouts and second layout features. For example, a distance between a layout feature of any target chip layout and any second layout feature may be calculated according to the formula of the Euclidean spatial distance or the formula of the cosine distance.

Step 5037: Select, for any target chip layout, a minimum second distance from distances between a layout feature (namely, a target layout feature) of the any target chip layout and the second layout features, and cluster the any target chip layout into a second cluster corresponding to a second layout feature corresponding to the second distance.

A smaller distance between the layout feature of the target chip layout and the second layout feature indicates that the layout feature of the target chip layout is more similar to the second layout feature, and both the layout feature of the target chip layout and the second layout feature are more capable of representing the same type of chip layout. Based on this principle, the minimum second distance may be selected from the distances between the layout feature of the any target chip layout and the second layout features. The second layout feature corresponding to the second distance is a second layout feature that is in the second layout features and that is most similar to the layout feature of the target chip layout. The target chip layout may be clustered into the second cluster corresponding to the second layout feature corresponding to the second distance.

In this manner, the plurality of target chip layouts may be clustered into a plurality of second clusters. Target chip layouts in the same second cluster correspond to the same type of chip layout. Therefore, in this manner, the target chip layouts may be clustered based on types of the chip layouts.

Step 5038: Use each second cluster as each target cluster when each second cluster meets the clustering end condition.

When each second cluster meets the clustering end condition, each second cluster is used as each target cluster. When each second cluster does not meet the clustering end condition, the plurality of target chip layouts may be clustered again in a manner of step 5035 to step 5038, until each target cluster is obtained.

The plurality of target chip layouts are clustered for a plurality of times in a manner of step 5031 to step 5038, so that a clustering center of a cluster can be continuously changed, target chip layouts in the same cluster are more similar, and target chip layouts in different clusters are more dissimilar, until the clustering end condition is met. That the clustering end condition is met is equivalent to that the cluster is converged, and the clustering center of the cluster does not fluctuate any more. Therefore, the target cluster obtained by clustering the plurality of target chip layouts for a plurality of times in the manner of step 5031 to step 5038 has a small an error and high accuracy.

Step 504: Obtain, through screening for any target cluster, a key chip layout from target chip layouts included in the any target cluster.

In this embodiment of this application, the target chip layouts included in the target cluster belong to the same chip layout type. Therefore, the key chip layout may be obtained by randomly sampling the target chip layouts included in the any target cluster. There is at least one key chip layout. The target chip layouts are clustered to obtain the target clusters, and the key chip layout is obtained, through screening, from target chip layouts included in each target cluster. This can avoid manually selecting the key chip layout from all the target chip layouts, and avoid interference of manual experience, random selection, and the like to a final result.

In a possible implementation, step 504 includes: obtaining distance between layout features of the target chip layouts in the any target cluster and a clustering center of the any target cluster; and evenly sampling, based on the distances between the layout features of the target chip layouts in the any target cluster and the clustering center of the any target cluster, the target chip layouts included in the any target cluster, to obtain a plurality of key chip layouts.

In this embodiment of this application, a clustering center of any target cluster may be an expected clustering center of the target cluster, or may be an actual clustering center of the target cluster. For a calculation manner of the expected clustering center of the target cluster, refer to determining content about the second layout feature. Implementation principles thereof are similar. For a calculation manner of the actual cluster center of the target cluster, refer to determining content about the actual cluster center of the first cluster. Implementation principles thereof are similar.

For any target cluster, a distance between a layout feature of any target chip layout included in the target cluster and a clustering center of the target cluster may be calculated according to the formula of the Euclidean spatial distance or the formula of the cosine distance. In this manner, distances between layout features of target chip layouts in the target cluster and the clustering center of the target cluster may be obtained.

In some embodiments, a maximum distance is determined from the distances between the layout features of the target chip layouts in the target cluster and the clustering center of the target cluster, and the maximum distance is divided by a sampling quantity to obtain a sampling interval. A sampling distance that is an integer multiple of the sampling interval is obtained, through screening, from the distances between the layout features of the target chip layouts in the target cluster and the clustering center of the target cluster. A key chip layout is obtained, through sampling, from a target chip layout corresponding to the sampling distance.

For example, it is assumed that there are M target clusters, and the sampling quantity is L+1. For any target cluster, a maximum distance is determined from distances between layout features of target chip layouts in the target cluster and a clustering center of the target cluster, and the maximum distance is divided by L+1 to obtain a sampling interval. Sampling distances that are 0, 1*sampling interval, 2*sampling interval, . . . , (L+1)*sampling interval are obtained, through screening, from the distances between the layout features of the target chip layouts in the target cluster and the clustering center of the target cluster, and the maximum distance. A total of L+2 target chip layouts are obtained, through sampling, from target chip layouts corresponding to these sampling distances. A layout feature of a target chip layout corresponding to the sampling distance 0 is the clustering center of the target cluster, and a distance between a layout feature of a target chip layout corresponding to the sampling distance “(L+1)*sampling interval” and the clustering center of the target cluster is the maximum distance. Because L+2 target chip layouts may be obtained from one target cluster through sampling, a total of M×(L+2) target chip layouts may be obtained from the M target clusters through sampling.

In a possible implementation, after step 504, the method further includes: performing source mask optimization on the key chip layout to obtain a target source and a mask layout corresponding to the key chip layout; and performing mask optimization on another chip layout based on the target source, to obtain a mask layout corresponding to the another chip layout, the another chip layout being a target chip layout other than the key chip layout in the target chip layouts.

In this embodiment of this application, performing source mask optimization on the key chip layout is equivalent to performing source mask optimization (SMO) on the key chip layout, so that the target source and the mask layout corresponding to the key chip layout can be obtained. SMO is a key resolution enhancement technology for implementing a nanometer (for example, 28 nanometers or even smaller) integrated circuit. The key chip layout is obtained from the target chip layouts through screening, and SMO is performed on the key chip layout, so that a quantity of key chip layouts can be less than a quantity of target chip layouts, thereby improving a speed of SMO. In addition, the target chip layouts are clustered, and the key chip layout is obtained, through screening, from target chip layouts included in each cluster. This can ensure that the key chip layout covers various chip layout types, and the key chip layout has less redundancy phenomenon, so that accuracy of the target source obtained by performing SMO on the key chip layout is high, and efficiency and an effect of SMO are improved.

SMO belongs to a source optimization (SO) technology. By changing intensity distribution of a source, the SMO technology may adjust intensity and a direction of incident light, so that quality of an imaging layout obtained by exposing the mask layout on a wafer by using the source is high, thereby helping improve chip yield. When SMO is performed on the key chip layout based on the method in this embodiment of this application, a speed and an effect of SMO can be improved. In this embodiment of this application, photolithography resolution can be improved, and a photolithography process window can be increased. In addition, the target chip layout in this embodiment of this application is a layout represented by using pixels. Therefore, the target chip layout has high universality, and may be applicable to chip layout types such as a contact hole type, a logical layout type, and a dense line type.

When any time of SMO is performed, any source may be used as an initial source, and a lithography machine is invoked to expose the key chip layout on photosensitive adhesive based on the initial source to obtain an intermediate mask layout. Then, the lithography machine is invoked to expose the intermediate mask layout on a wafer by using the initial source, to obtain an imaging layout. The imaging layout is compared with the key chip layout, to obtain an error between the imaging layout and the key chip layout.

In some embodiments, if the error between the imaging layout and the key chip layout meets an optimization condition, the initial source is used as the target source, the intermediate mask layout is used as the mask layout corresponding to the key chip layout, and the mask layout corresponding to the key chip layout is configured for invoking the lithography machine to expose, on the wafer by using the target source, the mask layout corresponding to the key chip layout, to obtain the imaging layout corresponding to the key chip layout. If the error between the imaging layout and the key chip layout does not meet the optimization condition, the initial source is adjusted based on the error between the imaging layout and the key chip layout to obtain an adjusted initial source. The adjusted initial source is used as an initial source of a next time of SMO, and the foregoing SMO is performed at least once based on the initial source, until the target source and the mask layout corresponding to the key chip layout are obtained.

In some embodiments, that the optimization condition is met is that the error between the imaging layout and the key chip layout falls within a specified error range. Alternatively, that the optimization condition is met is that a gradient of the error between the imaging layout and the key chip layout is less than a specified gradient threshold. In this case, when the initial source is adjusted based on the error between the imaging layout and the key chip layout, the initial source may be adjusted based on the gradient of the error between the imaging layout and the key chip layout.

Then, the lithography machine may be invoked to expose the another chip layout on the photosensitive adhesive based on the target source, to obtain the mask layout corresponding to the another chip layout. The mask layout corresponding to the another chip layout is configured for invoking the lithography machine to expose, on the wafer by using the target source, the mask layout corresponding to the another chip layout, to obtain the imaging layout corresponding to the another chip layout.

In some embodiments, if the key chip layout and the another chip layout are obtained by dividing one chip layout, after source mask optimization is performed on the key chip layout to obtain the target source, the lithography machine may be invoked to expose the chip layout on the photosensitive adhesive based on the target source, to obtain a mask layout corresponding to the chip layout. The mask layout corresponding to the chip layout is configured for invoking the lithography machine to expose, on the wafer by using the target source, the mask layout corresponding to the chip layout, to obtain an imaging layout corresponding to the chip layout.

Information (including but not limited to user device information, user personal information, and the like), data (including but not limited to data used for analysis, stored data, and displayed data), and a signal in this application are authorized by a user or fully authorized by each party, and related data needs to be collected, used, and processed in compliance with relevant national laws and standards. For example, the target chip layout in this application is obtained in case of full authorization.

According to the foregoing method, the chip layout encoder focuses on extracting a layout feature that can distinguish between chip layout types. Therefore, when the chip layout encoder is configured to extract the layout features of the target chip layouts, and perform clustering on the plurality of target chip layouts based on the layout features of the target chip layouts, target chip layouts of the same chip layout type can be accurately clustered into the same target cluster, and target chip layouts of different chip layout types are clustered into different target clusters, thereby improving accuracy of a clustering result. When the key chip layout is obtained, through screening, from target chip layouts included in any target cluster, redundancy of the key chip layout can be reduced, and screening quality can be improved.

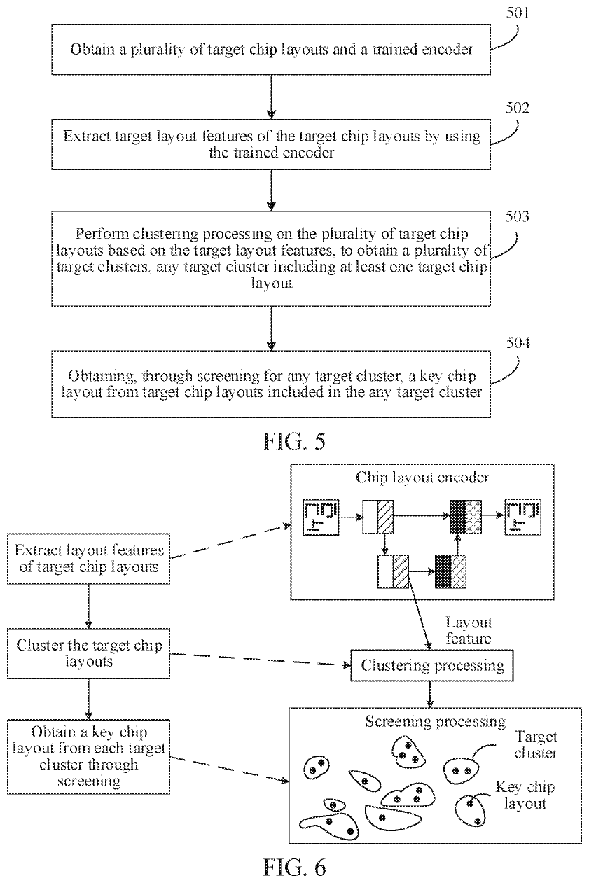

The foregoing describes, from the perspective of method steps, the method for training a chip layout encoder and the chip layout screening method provided in the embodiments of this application. The following further describes the method with reference to FIG. 6. FIG. 6 is a schematic diagram of a chip layout encoder and perform cluster screening based on the chip layout encoder according to an embodiment of this application.

In this embodiment of this application, a sample data set may be obtained, and a chip layout encoder is obtained by training an initial encoder by using the sample data set based on the method for training a chip layout encoder related to FIG. 2. The sample data set in this embodiment of this application includes two open-source data sets. One data set includes 4877 chip layouts, and the 4877 chip layouts may be used as sample chip layouts or a part of chip layouts may be extracted from the 4877 chip layouts as sample chip layouts. The other data set includes 5394 chip layouts, and the 5394 chip layouts may be used as sample chip layouts or a part of chip layouts may be extracted from the 5394 chip layouts as sample chip layouts. The sample chip layout is configured for training the initial encoder. In addition, the sample data set in this embodiment of this application further includes some chip layouts of a contact hole type, some chip layouts of a logical layout type, some chip layouts of a dense line type, and the like.

After the chip layout encoder is obtained through training, a key chip layout may be obtained from a plurality of target chip layouts through screening by using the chip layout encoder. For a structure of the chip layout encoder, refer to descriptions related to FIG. 4. Details are not described herein again.

In this embodiment of this application, layout features of the target chip layouts may be extracted by using the chip layout encoder. Then, the target chip layouts are clustered based on the layout features of the target chip layouts, to obtain a plurality of target clusters. Any target cluster includes at least one target chip layout. Subsequently, a key chip layout is obtained from each target cluster through screening. For example, for any target cluster, a key chip layout may be obtained, through screening, from target chip layouts included in the target cluster.

The foregoing chip layout encoder focuses on extracting a layout feature that can distinguish between chip layout types. Therefore, when the chip layout encoder is configured to extract the layout features of the target chip layouts, and perform clustering on the plurality of target chip layouts based on the layout features of the target chip layouts, accuracy of a clustering result can be improved. When the key chip layout is obtained from each target cluster through screening, redundancy of the key chip layout can be reduced, and screening quality can be improved.

FIG. 7 is a schematic structural diagram of an apparatus for training a chip layout encoder according to an embodiment of this application. As shown in FIG. 7, the apparatus includes:
an obtaining module 701, configured to obtain a sample chip layout and an initial encoder;
a transformation module 702, configured to perform geometric transformation on the sample chip layout to obtain at least one reference chip layout;
an extraction module 703, configured to extract a layout feature of the sample chip layout and a layout feature of each reference chip layout via the initial encoder, or an extraction module 703, configured to extract a sample layout feature of the sample chip layout and a reference layout feature of each reference chip layout by using the initial encoder; and
a training module 704, configured to train the initial encoder based on the layout feature (namely, the sample layout feature) of the sample chip layout and the layout feature (namely, the reference layout feature) of each reference chip layout, to obtain a chip layout encoder (namely, a trained encoder), the chip layout encoder being configured to extract a layout feature of a target chip layout.

In a possible implementation, the transformation module 702 is configured to: perform mirror flipping processing on the sample chip layout to obtain a symmetric chip layout; perform rotation processing on the sample chip layout and the symmetric chip layout to obtain a rotary chip layout; and use the symmetric chip layout and the rotary chip layout as the at least one reference chip layout. Alternatively, the transformation module 702 is configured to: perform mirror flipping on the sample chip layout to obtain a flipped chip layout; and rotate the sample chip layout and the flipped chip layout to obtain a rotated chip layout, the at least one reference chip layout including the flipped chip layout and the rotated chip layout.

In a possible implementation, the transformation module 702 is configured to: perform mirror flipping processing on the sample chip layout to obtain a symmetric chip layout, and use the symmetric chip layout as the at least one reference chip layout; or perform rotation processing on the sample chip layout to obtain a rotary chip layout, and use the rotary chip layout as the at least one reference chip layout. Alternatively, the transformation module 702 is configured to: perform mirror flipping on the sample chip layout to obtain a flipped chip layout, the at least one reference chip layout including the flipped chip layout; or rotate the sample chip layout to obtain a rotated chip layout, the at least one reference chip layout including the rotated chip layout.

In a possible implementation, the transformation module 702 is configured to: perform rotation processing on the sample chip layout to obtain a rotary chip layout; perform mirror flipping processing on the sample chip layout and the rotary chip layout to obtain a symmetric chip layout; and use the symmetric chip layout and the rotary chip layout as the at least one reference chip layout. Alternatively, the transformation module 702 is configured to: rotate the sample chip layout to obtain a rotated chip layout; and perform mirror flipping on the sample chip layout and the rotated chip layout to obtain a flipped chip layout, the at least one reference chip layout including the rotated chip layout and the flipped chip layout.

In a possible implementation, the extraction module 703 is configured to perform a plurality of times of downsampling processing on the sample chip layout via (that is, by using) the initial encoder, to obtain a downsampling feature obtained through each time of downsampling processing, the layout feature of the sample chip layout being a downsampling feature obtained through the last time of downsampling processing.

In a possible implementation, the apparatus further includes:
a reconstruction module, configured to determine a reconstructed chip layout based on the layout feature of the sample chip layout, the reconstructed chip layout being a chip layout reconstructed based on the layout feature of the sample chip layout.

The training module 704 is configured to train the initial encoder based on the sample chip layout, the reconstructed chip layout, the layout feature of the sample chip layout, and the layout feature of each reference chip layout, to obtain the chip layout encoder.

In a possible implementation, the reconstruction module is configured to perform a plurality of times of upsampling processing on the layout feature of the sample chip layout to obtain each upsampling feature, the reconstructed chip layout being a chip layout obtained based on an upsampling feature obtained through the last time of upsampling processing.

In a possible implementation, the reconstruction module is configured to: perform the first time of upsampling processing on the layout feature of the sample chip layout to obtain the first upsampling feature, the layout feature of the sample chip layout being obtained by performing a plurality of times of downsampling processing on the sample chip layout; and obtain, for any upsampling feature obtained through any time of upsampling processing, a downsampling feature corresponding to the any upsampling feature, a quantity of times of downsampling processing when downsampling processing is performed on the sample chip layout to obtain the downsampling feature corresponding to the any upsampling feature being a first quantity of times, a quantity of times of upsampling processing when upsampling processing is performed on the layout feature of the sample chip layout to obtain the any upsampling feature being a second quantity of times, and a sum of the first quantity of times and the second quantity of times being a target quantity of times; splice the any upsampling feature with the downsampling feature corresponding to the any upsampling feature, to obtain a spliced feature corresponding to the any upsampling feature; and perform upsampling processing on the spliced feature corresponding to the any upsampling feature, to obtain a next upsampling feature of the any upsampling feature.

In a possible implementation, the training module 704 is configured to: determine a first loss based on the layout feature of the sample chip layout and the layout feature of each reference chip layout; determine a second loss based on the sample chip layout and the reconstructed chip layout; and train the initial encoder based on the first loss and the second loss to obtain the chip layout encoder.

According to the foregoing apparatus, geometric transformation is performed on the sample chip layout to obtain the reference chip layout, and the initial encoder is trained by using the layout feature of the sample chip layout and the layout feature of the reference chip layout to obtain the chip layout encoder. Therefore, the chip layout encoder can output similar layout features for chip layouts before and after geometric transformation. The chip layouts before and after geometric transformation belong to the same chip layout type. Therefore, the chip layout encoder focuses on extracting a layout feature that can distinguish between chip layout types. This helps improve clustering accuracy and reduces redundancy of a screening result when clustering and screening are subsequently performed on chip layouts based on the layout feature.

It is to be understood that, when the apparatus provided in FIG. 7 implements the functions thereof, only division of the foregoing function modules is used as an example for description. In the practical application, the functions may be allocated to and completed by different function modules according to requirements. That is, an internal structure of the device is divided into different function modules, to complete all or some of the functions described above. In addition, the apparatus provided in the foregoing embodiment belongs to the same concept as the method embodiment. For a specific implementation process thereof, refer to the method embodiment, and details are not described herein again.

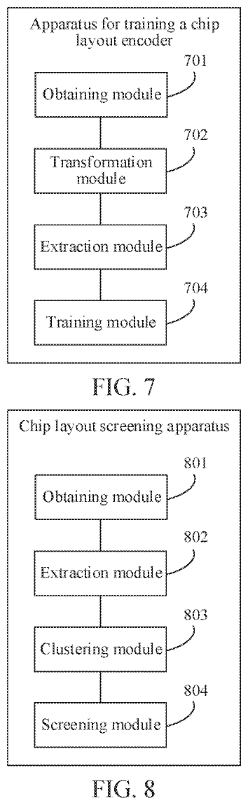

FIG. 8 is a schematic structural diagram of a chip layout screening apparatus according to an embodiment of this application. As shown in FIG. 8, the apparatus includes:
an obtaining module 801, configured to obtain a plurality of target chip layouts and a chip layout encoder (namely, a trained encoder), the chip layout encoder being obtained through training based on the foregoing method for training a chip layout encoder;
an extraction module 802, configured to extract layout features (namely, target layout features) of the target chip layouts by using the chip layout encoder;
a clustering module 803, configured to perform clustering on the plurality of target chip layouts based on the layout features (namely, the target layout features) of the target chip layouts, to obtain a plurality of target clusters, any target cluster including at least one target chip layout; and
a screening module 804, configured to obtain, through screening for any target cluster, a key chip layout from target chip layouts included in the any target cluster.

In a possible implementation, the clustering module 803 is configured to: obtain a plurality of first layout features, one first layout feature being configured for representing a clustering center of one first cluster; calculate distances between the layout features of the target chip layouts and the first layout features; select, for any target chip layout, a minimum first distance from distances between a target layout feature of the any target chip layout and the first layout features, and cluster the any target chip layout into a first cluster represented by a first layout feature corresponding to the first distance; and use each first cluster as each target cluster when each first cluster meets a clustering end condition.

In a possible implementation, the clustering module 803 is further configured to: determine, for any first cluster when each first cluster does not meet the clustering end condition, one second layout feature based on layout features of target chip layouts in the any first cluster, the one second layout feature being configured for representing a clustering center of one second cluster; calculate distances between the layout features of the target chip layouts and second layout features; select, for any target chip layout, a minimum second distance from distances between a target layout feature of the any target chip layout and the second layout features, and cluster the any target chip layout into a second cluster represented by a second layout feature corresponding to the second distance; and use each second cluster as each target cluster when each second cluster meets the clustering end condition.

In a possible implementation, the screening module 804 is configured to: obtain distances between layout features of target chip layouts in the any target cluster and a clustering center of the any target cluster; and evenly sample, based on the distances between the layout features of the target chip layouts in the any target cluster and the clustering center of the any target cluster, the target chip layouts included in the any target cluster, to obtain a plurality of key chip layouts.

In a possible implementation, the apparatus further includes:
an optimization module, configured to: perform source mask optimization on the key chip layout to obtain a target source and a mask layout corresponding to the key chip layout; and perform mask optimization on another chip layout based on the target source, to obtain a mask layout corresponding to the another chip layout, the another chip layout being a target chip layout other than the key chip layout in the target chip layouts.

According to the foregoing apparatus, the chip layout encoder focuses on extracting a layout feature that can distinguish between chip layout types. Therefore, when the chip layout encoder is configured to extract the layout features of the target chip layouts, and perform clustering on the plurality of target chip layouts based on the layout features of the target chip layouts, target chip layouts of the same chip layout type can be accurately clustered into the same target cluster, and target chip layouts of different chip layout types are clustered into different target clusters, thereby improving accuracy of a clustering result. When the key chip layout is obtained, through screening, from target chip layouts included in any target cluster, redundancy of the key chip layout can be reduced, and screening quality can be improved.

It is to be understood that, when the apparatus provided in FIG. 8 implements the functions thereof, only division of the foregoing function modules is used as an example for description. In the practical application, the functions may be allocated to and completed by different function modules according to requirements. That is, an internal structure of the device is divided into different function modules, to complete all or some of the functions described above. In addition, the apparatus provided in the foregoing embodiment belongs to the same concept as the method embodiment. For a specific implementation process thereof, refer to the method embodiment, and details are not described herein again.

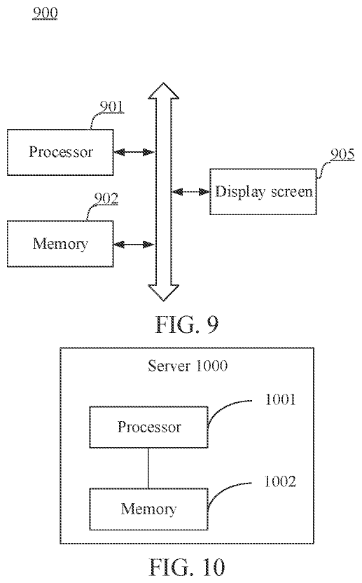

FIG. 9 is a structural block diagram of a terminal device 900 according to an exemplary embodiment of this application. The terminal device 900 includes: a processor 901 and a memory 902.

The processor 901 may include one or more processing cores, for example, a 4-core processor or an 8-core processor. The processor 901 may be implemented in at least one hardware form of a digital signal processor (DSP), a field-programmable gate array (FPGA), and a programmable logic array (PLA). The processor 901 may alternatively include a main processor and a coprocessor. The main processor is configured to process data in an active state, also referred to as a central processing unit (CPU). The coprocessor is a low-power processor configured to process data in a standby state. In some embodiments, the processor 901 may be integrated with a graphics processing unit (GPU). The GPU is configured to render and draw content that needs to be displayed on a display screen. In some embodiments, the processor 901 may further include an artificial intelligence (AI) processor. The AI processor is configured to process computing operations related to machine learning.

The memory 902 may include one or more non-transitory computer-readable storage media. The computer-readable storage medium may be non-transient. The memory 902 may further include a high-speed random access memory and a non-volatile memory, for example, one or more disk storage devices or flash storage devices. In some embodiments, the non-transient computer readable storage medium in the memory 902 is configured to store at least one computer program, and the at least one computer program is configured to be executed by the processor 901, so that the terminal device 900 implements the method for training a chip layout encoder or the chip layout screening method provided in the method embodiment of this application.

In some embodiments, the terminal device 900 further includes: a display screen 905.

The display screen 905 is configured to display a user interface (UI). The UI may include a graph, text, an icon, a video, and any combination thereof. When the display screen 905 is a touch display screen, the display screen 905 further has a capability of collecting a touch signal on or above a surface of the display screen 905. The touch signal may be inputted into the processor 901 as a control signal for processing. In this case, the display screen 905 may be further configured to provide a virtual button and/or a virtual keyboard that are/is also referred to as a soft button and/or a soft keyboard. In some embodiments, there may be one display screen 905 that is disposed on a front panel of the terminal device 900. In other embodiments, there may be at least two display screens 905 that are respectively disposed on different surfaces of the terminal 900 or that are folded. In still other embodiments, the display screen 905 may be a flexible display screen that is disposed on a curved surface or a folded surface of the terminal device 900. Even, the display screen 905 may be further disposed in a non-rectangular irregular pattern, namely, a special-shaped screen. The display screen 905 may be prepared by using materials such as a liquid crystal display (LCD), an organic light-emitting diode (OLED), or the like. For example, chip layouts such as a sample chip layout, a rotary chip layout, and a symmetric chip layout are displayed by using the display screen 905.

A person skilled in the art may understand that the structure shown in FIG. 9 does not constitute a limitation on the terminal device 900, and may include more or fewer components than those shown in the figure, or combine some components, or use different component arrangements.

FIG. 10 is a schematic structural diagram of a server according to an embodiment of this application. The server 1000 may have vary greatly due to different configurations or performance, and may include one or more processors 1001 and one or more memories 1002. The one or more memories 1002 store at least one computer program, and the at least one computer program is loaded and executed by the one or more processors 1001, so that the server 1000 implements the method for training a chip layout encoder or the chip layout screening method provided in the foregoing method embodiments. For example, the processor 1001 is a CPU. Certainly, the server 1000 may further include components such as a wired or wireless network interface, a keyboard, and an input/output interface, to perform input/output. The server 1000 may further include another component configured to implement a device function. Details are not described herein.

In an exemplary embodiment, a non-transitory computer-readable storage medium is further provided, storing at least one computer program, the at least one computer program being loaded and executed by a processor, so that an electronic device implements any one of the foregoing training methods for a chip layout encoder or the foregoing chip layout screening methods.

In some embodiments, the computer-readable storage medium may be a read-only memory (ROM), a random access memory (RAM), a compact disc read-only memory (CD-ROM), a magnetic tape, a floppy disk, an optical data storage device, or the like.

In an exemplary embodiment, a computer program is further provided, there being at least one computer program, and the at least one computer program being loaded and executed by a processor, so that an electronic device implements any one of the foregoing training methods for a chip layout encoder or the foregoing chip layout screening methods.

In an exemplary embodiment, a computer program product is further provided, having at least one computer program stored therein, the at least one computer program being loaded and executed by a processor, so that an electronic device implements any one of the foregoing training methods for a chip layout encoder or the foregoing chip layout screening methods.

It is to be understood that “plurality of” mentioned in the specification means two or more. “And/or” describes an association relationship of an associated object, indicating that three relationships may exist. For example, A and/or B may indicate: A exists alone, both A and B exist, and B exist alone. The character “/” generally indicates an “or” relationship between associated objects before and after the character. In this application, the term “module” in this application refers to a computer program or part of the computer program that has a predefined function and works together with other related parts to achieve a predefined goal and may be all or partially implemented by using software, hardware (e.g., processing circuitry and/or memory configured to perform the predefined functions), or a combination thereof. Each module can be implemented using one or more processors (or processors and memory). Likewise, a processor (or processors and memory) can be used to implement one or more modules. Moreover, each module can be part of an overall module that includes the functionalities of the module.

The sequence numbers of the foregoing embodiments of this application are merely for description purpose, and are not intended to indicate priorities of the embodiments.

The foregoing descriptions are merely exemplary embodiments of this application, but are not intended to limit this application. Any modification, equivalent replacement, or improvement made within the principle of this application shall fall within the protection scope of this application.

What is claimed is:

1. A chip layout screening method performed by an electronic device, the method comprising:
extracting target layout features of a plurality of target chip layouts by using a chip layout encoder;
performing clustering on the plurality of target chip layouts based on the target layout features to obtain a plurality of target clusters, wherein each target cluster comprises a group of target chip layouts; and
identifying a key chip layout from a respective group of target chip layouts.

2. The method according to claim 1, wherein the performing clustering on the plurality of target chip layouts based on the target layout features to obtain a plurality of target clusters comprises:
obtaining a plurality of first layout features;
calculating distances between the target layout features of the plurality of target chip layouts and each first layout feature of the plurality of first layout features; and
for a target chip layout, clustering the target chip layout to a first cluster.

3. The method according to claim 2, wherein each first layout feature represents a center of a corresponding one of the plurality of target clusters.

4. The method according to claim 2, wherein a distance between a target layout feature of the target chip layout and the first layout feature of the first cluster is a minimum among distances between the target layout feature of the target chip layout and the plurality of first layout features.

5. The method according to claim 1, wherein the identifying a key chip layout from a respective group of target chip layouts comprises:
obtaining distances between layout features of the target chip layouts in the group and a clustering center of a target cluster corresponding to the group of target chip layouts; and
evenly sampling the target chip layouts in the group to obtain a plurality of key chip layouts based on the distances between the layout features of the target chip layouts in the group and the clustering center of the target cluster corresponding to the group of target chip layouts.

6. The method according to claim 1, further comprising:
performing source mask optimization on the key chip layout to obtain a target source and a mask layout corresponding to the key chip layout; and
performing mask optimization on another chip layout based on the target source, to obtain a mask layout corresponding to the another chip layout, the another chip layout being a target chip layout other than the key chip layout in the target chip layouts.

7. An electronic device, comprising a processor and a memory, the memory storing at least one computer program that, when executed by the processor, causes the electronic device to implement a chip layout screening method including:
extracting target layout features of a plurality of target chip layouts by using a chip layout encoder;
performing clustering on the plurality of target chip layouts based on the target layout features to obtain a plurality of target clusters, wherein each target cluster comprises a group of target chip layouts; and
identifying a key chip layout from a respective group of target chip layouts.

8. The electronic device according to claim 7, wherein the performing clustering on the plurality of target chip layouts based on the target layout features to obtain a plurality of target clusters comprises:
obtaining a plurality of first layout features;
calculating distances between the target layout features of the plurality of target chip layouts and each first layout feature of the plurality of first layout features; and
for a target chip layout, clustering the target chip layout to a first cluster.

9. The electronic device according to claim 8, wherein each first layout feature represents a center of a corresponding one of the plurality of target clusters.

10. The electronic device according to claim 8, wherein a distance between a target layout feature of the target chip layout and the first layout feature of the first cluster is a minimum among distances between the target layout feature of the target chip layout and the plurality of first layout features.

11. The electronic device according to claim 7, wherein the identifying a key chip layout from a respective group of target chip layouts comprises:
obtaining distances between layout features of the target chip layouts in the group and a clustering center of a target cluster corresponding to the group of target chip layouts; and
evenly sampling the target chip layouts in the group to obtain a plurality of key chip layouts based on the distances between the layout features of the target chip layouts in the group and the clustering center of the target cluster corresponding to the group of target chip layouts.

12. The electronic device according to claim 8, wherein the method further comprises:
performing source mask optimization on the key chip layout to obtain a target source and a mask layout corresponding to the key chip layout; and
performing mask optimization on another chip layout based on the target source, to obtain a mask layout corresponding to the another chip layout, the another chip layout being a target chip layout other than the key chip layout in the target chip layouts.

13. A non-transitory computer-readable storage medium, storing at least one computer program that, when executed by a processor of an electronic device, causes the electronic device to implement a chip layout screening method including:
extracting target layout features of a plurality of target chip layouts by using a chip layout encoder;
performing clustering on the plurality of target chip layouts based on the target layout features to obtain a plurality of target clusters, wherein each target cluster comprises a group of target chip layouts; and
identifying a key chip layout from a respective group of target chip layouts.

14. The non-transitory computer-readable storage medium according to claim 13, wherein the performing clustering on the plurality of target chip layouts based on the target layout features to obtain a plurality of target clusters comprises:
obtaining a plurality of first layout features;
calculating distances between the target layout features of the plurality of target chip layouts and each first layout feature of the plurality of first layout features; and
for a target chip layout, clustering the target chip layout to a first cluster.

15. The non-transitory computer-readable storage medium according to claim 14, wherein each first layout feature represents a center of a corresponding one of the plurality of target clusters.

16. The non-transitory computer-readable storage medium according to claim 14, wherein a distance between a target layout feature of the target chip layout and the first layout feature of the first cluster is a minimum among distances between the target layout feature of the target chip layout and the plurality of first layout features.

17. The non-transitory computer-readable storage medium according to claim 13, wherein the identifying a key chip layout from a respective group of target chip layouts comprises:
obtaining distances between layout features of the target chip layouts in the group and a clustering center of a target cluster corresponding to the group of target chip layouts; and
evenly sampling the target chip layouts in the group to obtain a plurality of key chip layouts based on the distances between the layout features of the target chip layouts in the group and the clustering center of the target cluster corresponding to the group of target chip layouts.

18. The non-transitory computer-readable storage medium according to claim 13, wherein the method further comprises:
performing source mask optimization on the key chip layout to obtain a target source and a mask layout corresponding to the key chip layout; and
performing mask optimization on another chip layout based on the target source, to obtain a mask layout corresponding to the another chip layout, the another chip layout being a target chip layout other than the key chip layout in the target chip layouts.
